(19) United States
(12) Patent Application Publication
(10) Pub. No.: US 2010/0101634 A1
(43) Pub. Date: Apr. 29, 2010

(54) THIN PROFILE SOLAR PANEL ROOF TILE

(76) Inventors: CHRISTOPHER FRANK, Rough and Ready, CA (US); John Montello, El Cajon, CA (US); Christopher S. Gopal, La Jolla, CA (US); Mike Curtis, Temewia, CA (US); Anand Janaswamy, Cardiff, CA (US); Mark Farrelly, Carlsbad, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 12/557,436

(22) Filed: Sep. 10, 2009

Related U.S. Application Data
(63) Continuation-in-part of application No. 12/258,360, filed on Oct. 24, 2008.

(51) Int. Cl. H01L 31/048; H05K 13/00

(52) U.S. Cl. 136/251; 29/592.1

(57) ABSTRACT

The present invention is directed toward apparatuses, systems and methods for solar panels capable of rooftop installation. In some embodiments, a low profile solar panel is provided, comprising: a solar laminate; and a flexible material sheet adhered to the solar laminate, wherein the flexible material sheet is configured to operate as a frame that supports and houses the solar laminate. In some such embodiments, the low profile solar panel further comprises a secondary sheet, wherein the secondary sheet is disposed on an edge formed by adhering the flexible material sheet to the solar laminate.

### RELATED APPLICATIONS

This application is a continuation-in-part of and claims the benefit of U.S. patent application Ser. No. 12/258,360 filed Oct. 24, 2008, which is incorporated herein by reference in its entirety.

### FIELD OF THE INVENTION

The present invention relates to apparatuses, systems and methods for solar power generation, and more particularly, to apparatuses, systems and methods for solar panels capable of rooftop installation.

### DESCRIPTION OF THE RELATED ART

Increasing oil prices and environmental concerns have recently highlighted the desire to decrease the dependence on fossil fuels. This desire has stimulated research into clean and renewable ways to produce electricity for the global marketplace. Solar power is a viable option because it is a clean form of energy with a virtually unlimited supply. Technological innovations and improvements are generally reducing the costs associated with installing, operating, and maintaining solar power equipment. Furthermore, conversion efficiencies have dramatically increased over the years, thereby reducing the size of the equipment necessary to harvest energy produced by the sun.

In some cases, solar energy systems may be used in lieu of oil or other fossil fuels. For example, some solar energy systems may use solar or photovoltaic cells. A solar or photovoltaic (“PV”) cell is a device that converts energy from the sun or other light source into electrical energy. The use of PV cells as an alternative to other sources of energy has generally increased as power costs have increased. For example, some owners of commercial and residential buildings have used certain systems to install PV cells on the top of their buildings to reduce the building's overall dependence on energy provided by utility companies.

Unfortunately, systems for mounting PV cells generally are generally difficult to install, and are fragile once they are installed. Typically, an installation requires roof racks that may result in roof penetrations and exert wind loads on the roof. Additionally, in order to generate a significant amount of power, the system generally must include a large number of panels with PV cells, which can create issues with wiring and connections to the existing utility systems. Systems for mounting PV cells also tend to lack curb appeal, as they often change the aesthetics of a structure, e.g., a residential structure.

### BRIEF SUMMARY OF EMBODIMENTS OF THE INVENTION

The present invention is directed toward apparatuses, systems and methods for solar panels capable of rooftop installation. In some embodiments, a low profile solar panel is provided, comprising: a solar laminate; and a flexible material sheet adhered to the solar laminate, wherein the flexible material sheet is configured to operate as a frame that supports and houses the solar laminate. In some such embodiments, the low profile solar panel further comprises a secondary sheet, wherein the secondary sheet is disposed on an edge formed by adhering the flexible material sheet to the solar laminate.

In other embodiments, the low profile solar panel further comprises electrical wiring or circuitry disposed on the solar laminate. For some such embodiments, the low profile solar panel further comprises a secondary sheet, wherein the secondary sheet is disposed on an edge formed by adhering the flexible material sheet to the solar laminate, such that the secondary sheet covers the electrical wiring or circuitry.

In various embodiments of the invention, the low profile solar panel is configured to be attached to a roof. In some such embodiment, the low profile solar panel is attached to the roof by nails, screws, foam, a tack-down strip or adhesives. Additionally, in certain embodiments, the tack-down strip is configured to connect the low profile solar panel to overlap a roof shingle or roof tile.

In particular embodiments, the low profile solar panel is configured to integrate with roof shingles or roof tiles. For example, the low profile solar panel may be configured to integrate with asphalt shingles. In addition, the low profile solar panel of some embodiments is less than 0.65″ thick.

Further, in order to adhere the flexible material sheet to the solar laminate, some embodiments utilize adhesives. Additionally, in some embodiments, the solar laminate comprises multiple solar cells. Some embodiments feature an integrated rain-rail disposed on the solar laminate configured to provide a conduit for rainwater and mate with a rain rail on a second solar panel, providing a mechanical interconnection between the low profile solar panel and the second solar panel.

For some embodiments, the low profile solar panel further comprises an integrated rain-rail disposed on the secondary sheet configured to provide a conduit for rainwater and mate with a rain rail on a second solar panel providing a mechanical interconnection between the low profile solar panel and the second solar panel.

In other embodiments, a method for mounting solar panels onto a roof is provided, comprising: providing a first solar panel, comprising: a solar laminate, and a flexible material sheet adhered to the solar laminate, wherein the flexible material sheet is configured to operate as a frame that supports the solar laminate, houses the solar laminate, and interfaces with a conventional roof shingle or roof tile in an overlapping fashion; overlapping a roof shingle or roof tile over an upper portion of the first solar panel; securing the first solar panel to the roof; and overlapping a second solar panel over the upper portion of the first solar panel.

In various embodiments, the first solar panel further comprises a secondary sheet, wherein the secondary sheet is disposed on an edge formed by adhering the flexible material sheet to the solar laminate. In additional embodiments, the first solar panel further comprises electrical wiring or circuitry disposed on the solar laminate. In some such embodiments, the first solar panel further comprises a secondary sheet, wherein the secondary sheet is disposed on an edge formed by adhering the flexible material sheet to the solar laminate, such that the secondary sheet covers the electrical wiring or circuitry.

For particular embodiments, the first solar panel is secured to the roof using nails, screws, foam, a tack-down strip, or adhesives. In some of those embodiments, the tack-down strip is used to overlap and connect the first solar panel to a roof shingle or roof tile.

In further embodiments, a building is provided, comprising: a roof assembly including roof shingles or roof tiles; and a low profile solar panel, comprising: a solar laminate, and a flexible material sheet adhered to the solar laminate, wherein the flexible material sheet is configured to operate as a frame that supports the solar laminate, houses the solar laminate, and interfaces with a conventional roof shingle or roof tile in an overlapping fashion. For some of these embodiments, the first solar panel further comprises a secondary sheet, wherein the secondary sheet is disposed on an edge formed by adhering the flexible material sheet to the solar laminate.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 is a diagram illustrating a roof including an example solar panel in accordance with an embodiment of the invention.

FIG. 2 is a diagram that illustrates an example solar laminate that may be used in conjunction with the systems and methods described herein.

FIG. 3 is a diagram illustrating an example solar panel in accordance with the apparatuses, systems and methods described herein.

FIG. 4 is a diagram illustrating the solar panel and the rain rail in accordance with the apparatuses, systems and methods described herein.

FIG. 5 is a diagram illustrating an example jumper in accordance with the apparatuses, systems and methods described herein.

FIG. 6 is a diagram illustrating two example solar panels in accordance with the apparatuses, systems and methods described herein.

FIG. 7 is a diagram illustrating an example construction of a low profile solar panel in accordance with the apparatuses, systems and methods described herein.

FIG. 8 is a diagram illustrating an example low profile solar panel in accordance with the apparatuses, systems and methods described herein

FIG. 9 is a flowchart of an example method for mounting a low profile solar panel in accordance with one embodiment of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

The present invention is directed toward apparatuses, systems and methods for solar panels capable of rooftop installation. In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

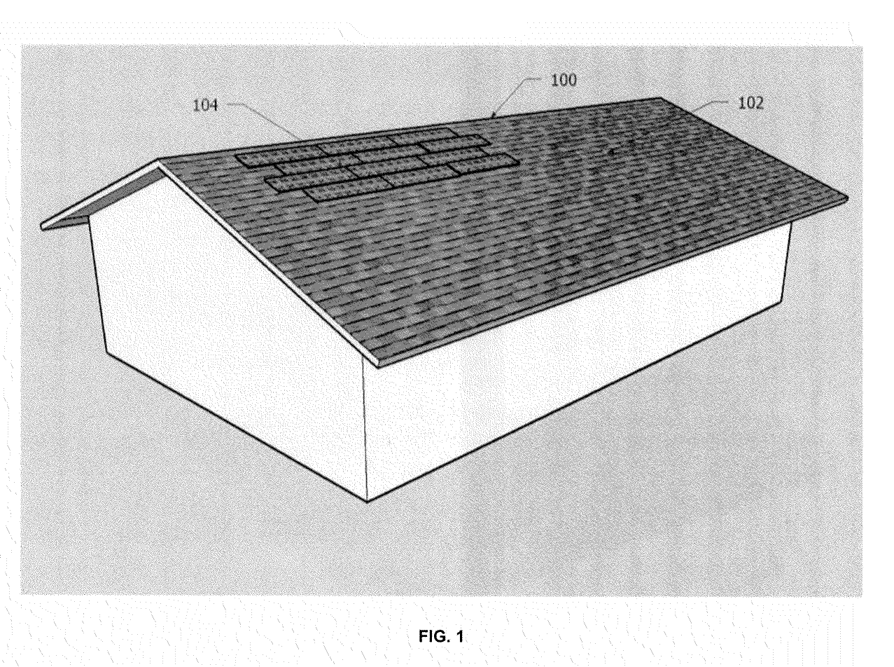

Referring now to the Figures, which are illustrative of multiple embodiments of the system of the present invention only and are not for purposes of limiting the same, FIG. 1 is a diagram illustrating a roof including an example set of solar panels in accordance with an embodiment of the invention. Referring now to FIG. 1, a roof, 100 is illustrated. The roof includes a number of shingles 102. The shingles 102 may be, for example, asphalt shingles, however, it will be understood that many other types of roof shingles may be used. Additionally, as illustrated in FIG. 1, the roof 100 may also include a solar panel 104.

The solar panel 104 may convert solar energy into electrical energy. This electricity may then be used by the homeowner to power the home, provide electrical energy back to the power grid to decrease electrical energy bills, or any other electrical use. In some example systems, solar panels may provide direct current electrical power. It will be understood that, in some embodiments, a system may convert this current to an alternating current electrical power source.

In another embodiment, a solar panel may collect solar energy to provide heat. The heat might increase the temperature of water or other liquid so that the heat might be carried into the home. The heat might then be used heat the home. In some examples, the water might be used for showering, laundry, etc. In some cases, the water might be in a sealed system that heats water in the home using a heat exchanger. The water heated using the heat exchanger might then be used for various purposes, such as showering, laundry, etc.

The example embodiment of FIG. 1 illustrates a solar power system that integrates the solar panels with roofing tiles. It will be understood, however, that in some embodiments, a roof might be entirely or almost entirely made using solar panels in accordance with the systems and methods described herein. Additionally, while the example illustrates solar panels that are incorporated into the roof 100, in some embodiments, the solar panels might form a new roof over an existing, e.g., shingle roof.

In some embodiments, a solar panel may be a thin profile, such that it might be incorporated into a shingle roof. For example, the solar panel might be installed similarly to roofing shingles, as illustrated in FIG. 1. These “solar shingles” may be connected to each other using a universal connector or jumper that can reverse polarity. The universal connector may facilitate stringing the panels together. By allowing polarity of the connection to be changed based on the orientation of a connector or jumper, the shingles may be installed and connected in various ways and configurations. For example, the shingles may be connected in parallel, in serial, or some combination of parallel and serial.

The solar panel 104 may comprise a solar cell or multiple solar cells. The solar cell or cells may be formed in a laminate. A laminate is a combination of one or more solar cells laminated with another material, e.g., a solar glass that efficiently collects more light to be converted to electrical energy by the solar cell. In this way, the laminated solar cells might be used to convert light in a broad range of frequency ranges to electrical energy.

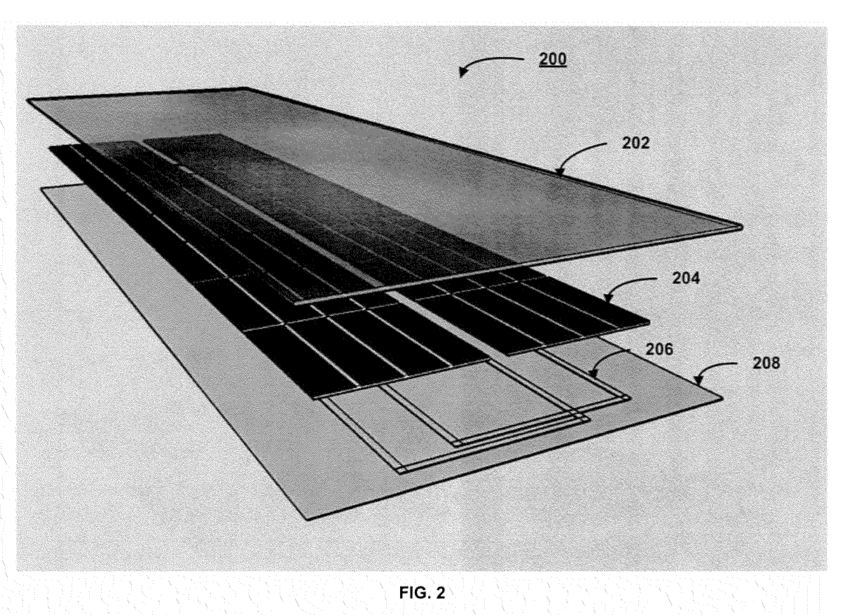

FIG. 2 is a diagram that illustrates an example laminate solar cell 200 that may be used in conjunction with the systems and methods described herein. Referring now to FIG. 2, a laminate solar cell 200 may convert light energy from the sun to electricity. The example laminate solar cell 200 includes 16 solar cells laminated to a glass panel 202. The example 16 solar cells form a cell array 204. The solar cells in the cell array 204 are wired together using a bus array 206 and bonded with other cells to form the laminate solar laminate 200.

Some embodiments feature a sealed solar cell assembly to keep out moisture, dust, debris and prevent tampering, etc. For example, laminate cell 200 may be protected by the glass panel 202 and sealed in a protective container, including a back sheet 208. The glass panel 202 allows light to reach the solar cell 200, while generally protecting the solar cell from insects, animals, and contaminants such as rain, dust, smoke, etc. While 16 solar cells are illustrated in the example cell array 204 of FIG. 2, it will be understood that other embodiments may include a different number of solar cells. Additionally, these cells may be wired together in series, in parallel, or some combination thereof.

In various embodiments, the solar cell assembly 200 may have a thin profile such that it may be installed similarly to shingles, as discussed above. The solar cell assembly 200 may lie flat or nearly flat on a roof. Generally, it will lie at a slight angle to allow one cell assembly 200 to overlap with another cell assembly 200 or a roofing shingle. The cell assemblies 200 may lay directly on a prepared roof deck, rolled or torched down underlayment on plywood, the plywood placed, e.g., on the framing of the roof or. In other embodiments, the solar panel laminates 200 may form a new roof placed over a pre-existing roof. The new roof may be placed directly on the existing roof or above the existing roof. In some cases, the laminates may be integrated into an existing shingle roof by removing some of the shingles on the roof and replacing them with solar panels 200.

Similar to the installation of shingles, the solar panel 200 might be attached to a roof using, for example, nails, screws, adhesive foam, etc. In this way, the solar panels 200 may be an integral part of a shingle roof. Additionally, the panels 200 might be installed by roofers having experience installing shingles and capable of applying that experience to installing the solar panels. For example, in some cases, the roofers might install the shingles without the assistance of a licensed electrician or solar integrator.

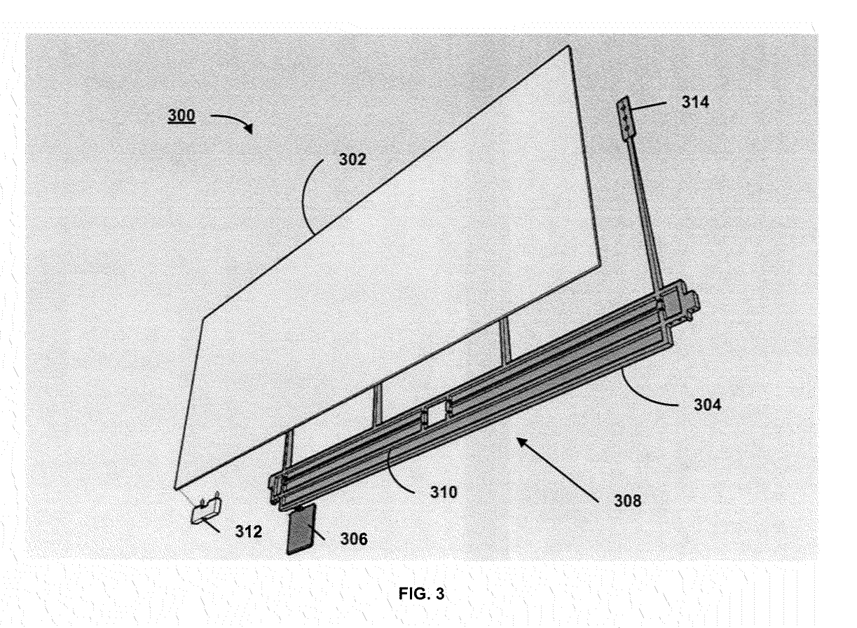

FIG. 3 is a diagram illustrating an example solar panel 300 in accordance with the systems and methods described herein. Referring now to FIG. 3, the solar panel 300 includes a photovoltaic glass laminate 302. The laminate may be the same or similar to the solar laminate 200 of FIG. 2. This laminate 302 may convert solar energy to electrical energy. The energy may be used by the homeowner, as described above.

The solar panel 300 includes a frame 304, which provides support for the photovoltaic glass laminate 302. The photovoltaic glass laminate 302 may be made of tempered glass, which can be laminated to a crystalline solar cell. The tempered glass provides protection and structural support to the crystalline solar cell. The crystalline solar cell converts solar energy into electrical energy. In some example systems, a mono-crystalline solar cell may be used. In some example systems, an amorphous solar cell may be used. In some example systems, a nano device solar cell may be used. In other embodiments, a polycrystalline solar cell may be used. Additionally, mono and poly crystalline cells or others might be used together, e.g., in separate solar panels on a single roof, within a single solar panel, etc.

In some examples, the frame 304 may be injection molded plastic. Adhesives may be used to connect various components, such as injection molded plastic components. For example, the plastic frame might be connected together using glue, epoxy resin, or other adhesive. Additionally, the frame 304 may include a wind clip 306. The wind clip 306 can help secure the solar panel 300 to a roof. For example the wind clip 306 may be secured under a frame of a second solar panel, e.g., at wind clip position 308 on the second panel. Accordingly, the second panel generally holds the first panel onto the roof such that if the first panel begins to lift, the wind clip 306 pushes against the second panel.

The frame 304 may include a water-shedding channel such as a rain-rail. The rain-rail is configured to provide a conduit for rainwater and mate with a rain-rail on another solar panel to provide a mechanical interconnection between the panels.

In the illustrated example, the frame provides a busway 310 that includes an electrical connection system. The example frame 304 includes busways, such as busway 310, which may be used to run electrical wiring for the solar panel 300. The busway 310 may also provide wiring using, e.g., a PC or circuit board. For example, the busway might contain a circuit board with traces in the board that are used to carry electrical signals. In some embodiments, this wiring might also be included in the laminate panel. Accordingly, the wiring is generally part of the solar panel. This or other wiring may connect to a jumper 312 that provides for a connection between panels 300. The jumper 312 may be a universal connector that can reverse polarity for easy stringing, e.g., connecting multiple panels together. In some embodiments, the jumper is sufficiently thin to allow the solar panel 300 to be integrated into a roof that is shingled with conventional shingles.

Various solar panel embodiments that integrate with conventional shingles may be manufactured to be about the same thickness as conventional shingles, for example, conventional asphalt shingles. In other embodiments, however, the solar panels 300 might be thicker or thinner than a conventional shingle. For example, a solar panel 300 that is thinner than a conventional shingle might then be covered by additional tempered glass, or some other clear material to provide further protection. In another example, a solar panel 300 might be thicker than a conventional shingle. A solar panel 300 that is thicker than a conventional shingle might block the flow of water down the slope of a roof on which it is installed. Such a solar panel 300 may include a rain rail or other features to divert water around the solar panel 300. In other embodiments, the solar panels 300 might be installed higher along the roof, e.g., two solar panels 300 might form the ridgeline of the roof. In this way, water might run down the solar panels 300 and onto any conventional shingles lower along the roof Conventional shingles may come in many shapes and sizes. Generally, they may be square or rectangular and may be from ⅛″ to ⅜″ thick.

Additionally, a tack-down strip, such as nailing tabs 314 can connect the solar panel to a roof. These tack-down strips may be used with, e.g., nails, screws, adhesive foam, or other methods of attachment. Additionally, the tack-down strip is configured to overlap a shingle on a roof. In some embodiments, multiple nailing tabs 314 may be used.

In some embodiments, a solar panel 300 may use integrated interconnections and bussing between panels 300. In this way, the panels may be produced such that they can be installed similarly to roofing shingles. In some embodiments, the installation may be accomplished without running a large amount of separate wiring. By decreasing the wiring required, the systems and methods described herein might be more likely to be used by roofers to install such a solar panel roofing system, as opposed to electricians or solar integrators. For example, the systems and methods described herein might integrate with three tab asphalt shingles.

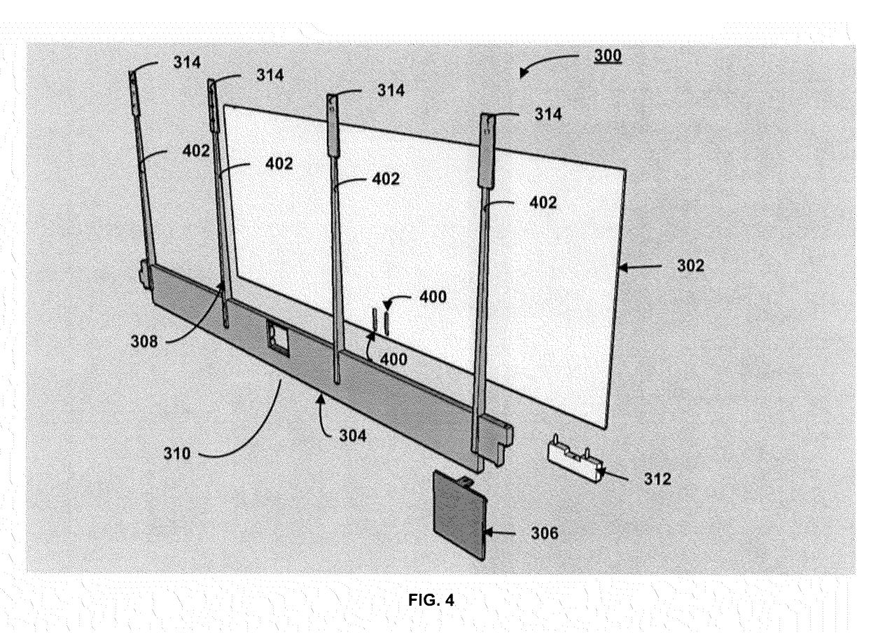

FIG. 4 is a diagram illustrating the solar panel 300 in accordance with the systems and methods described herein. Referring now to FIG. 4, the illustrated example solar panel 300 includes leads 400. These leads 400 provide electrical connection between the solar photovoltaic glass laminate 302 and the wiring or other electrical connection that runs through busway 310. In various embodiments, the leads 400 are coupled to jumper 312. For example, wires may connect to the leads 400. This might be done directly, e.g., by soldering, or by some form of connector. In another embodiment, the leads 400 might connect to board traces or other types of electrical connector.

FIG. 4 also includes ribs 402 that, in some embodiments, provide support for the photovoltaic glass laminate 302. This may allow the solar panel 300 to support additional weight. For example, some solar panels 300 might support a person walking onto them when, e.g., they are installed on a roof of a building.

The tempered glass, ribs 402 and frame of the solar panel 300 may allow for use in high wind areas, areas where extreme weather conditions are common and other areas where a thin film solar installation might be more likely to be damaged. In some cases, the solar panel 300 might better survive these types of conditions.

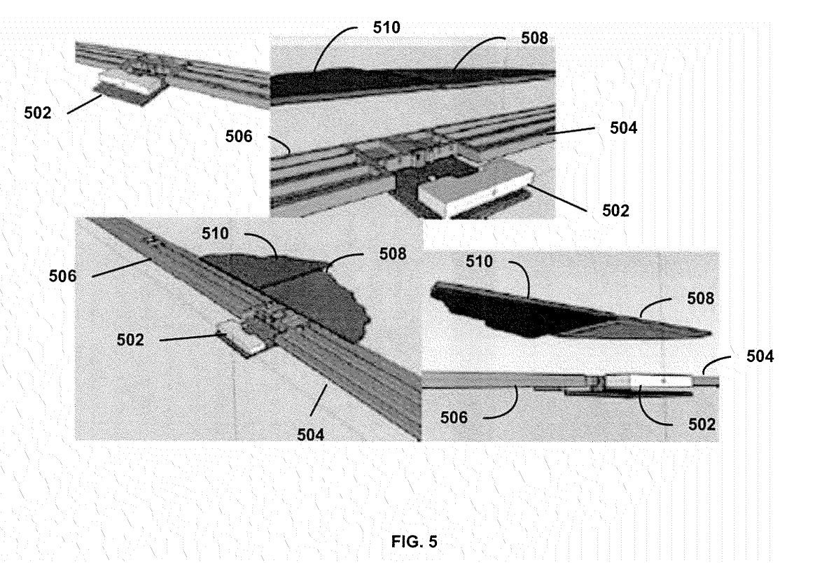

FIG. 5 is a diagram illustrating an example jumper 502 in accordance with the systems and methods described herein. Referring now to FIG. 5, the jumper 502 may be a universal connector or universal plug that is used to connect one solar panel to another. The polarity of the jumper 502 may be user configurable. For example, the polarity might be changed simply by flipping the plug over, e.g., changing the orientation of the jumper 502.

The jumper 502 plugs into a pair of frames 504 and 506. The frames 504 and 506 include busways such that connections and bussing may be integrated into the panel itself. For example, in some embodiments, wires may run through a busway in frame 504 and provide an electrical contact to jumper 502. This jumper may provide electrical contact to wires in a busway in frame 506. In this way, solar cells 508 and 510 may be connected together. These connections may connect multiple solar cells in parallel, in series, or some combination thereof. In some embodiments, the jumper plug 502 may provide an electrical connection in a small form factor, such as, for example, a smaller height so that a thinner solar cell may be made.

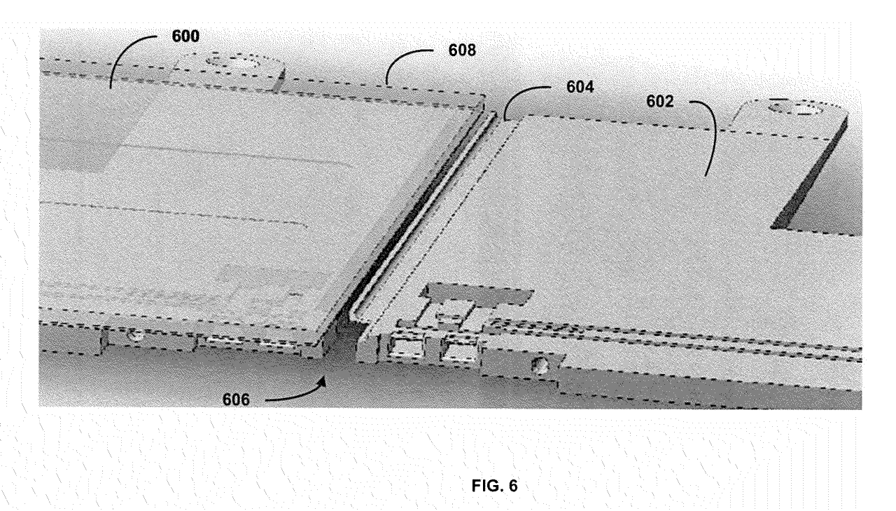

FIG. 6 is a diagram illustrating two example solar panels 600 and 602. Referring now to FIG. 6, the solar panel 602 includes a rain rail 604. In some embodiments, the solar panel 600 may also include a rain rail. The rain rail 604 may be made of the same materials as the rest of the frame of the solar panel 602. For example, in some embodiments, plastic may be used. The rain rail 604 will generally collect water that runs along the glass panel 608 of solar panel 600 and over the edge between the glass panel 608 and the glass panel of solar panel 602. The glass panel of solar panel 602 is not shown in FIG. 6 to allow the rain rail 604 and electrical connection area 606 to be illustrated. The rain rails 604 may be configured to connect to rain rails on other solar panels, e.g., so that water collected by one rain rail can runs from one panels to another until it runs off of the roof.

Electrical connection area 606 is configured to receive a connector or jumper. The connector may be the same or similar to the connector or jumper 312 of FIGS. 3 and 4 or the connector or jumper 502 of FIG. 5. In some embodiments, a connector is designed to connect the solar panels 600 and 602 in series or parallel depending on the orientation of the connector, e.g., one orientation makes a series connection, while another orientation makes a parallel connection. A parallel connection may be made, e.g., when a positive terminal on the solar panel 600 is connected to a positive terminal on the solar panel 602 and a negative terminal on solar panel 600 is connected to a negative terminal on a solar panel 602. Installing the connector in a first orientation makes at least some of these connections. It will be understood by those of skill in the art that additional solar panels may be added in parallel.

A series connection may be made, e.g., when a negative terminal on the solar panel 600 is connected to ground, the positive terminal on the solar panel 600 is connected to a negative terminal on the solar panel 602, and the positive terminal on solar panel 602 is connected to power. Installing the connector in a second orientation may form at least some of these connections. It will be understood that additional solar panels may be added in series and that a combination of series and parallel solar panels may also be employed in some embodiments.

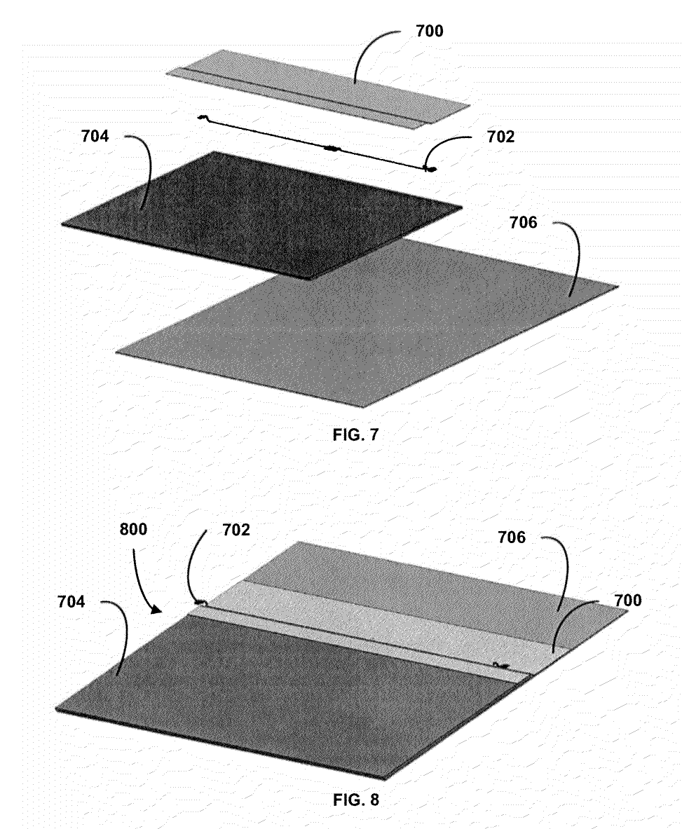

FIGS. 7 and 8 provide diagrams illustrating an example low profile solar panel in accordance with an embodiment of the invention. Referring now to FIG. 7, the diagram illustrates a low profile solar panel comprising a solar laminate 704, a flexible material sheet 706, electrical wiring and circuitry 702, and a secondary sheet 700. In some embodiments, the secondary sheet and the flexible material sheet may be of the same material. Some suitable materials for the flexible material sheet include, but are in no way limited to, Tedlar® and glass. For some embodiments, a suitable material for the secondary sheet can include Tedlar®.

As illustrated, the flexible material sheet 706 is adhered to the solar laminate 704, thereby creating an edge between the two layers due to the longer length of the flexible material sheet 706. The electrical wiring and circuitry 702, which electrically couples the solar laminate to the solar power system, is disposed on the solar laminate. Subsequently, the secondary sheet 700 may placed over the 704/706 edge and the electrical wiring and circuitry 702, thereby enclosing both (as illustrated).

The fully assembled low profile solar panel that results from FIG. 7 is illustrated in FIG. 8 as solar panel 800. It should be noted that once the second sheet 700 is placed over the electric wiring and circuitry 702, a portion of the electrical wiring and circuitry may remains exposed outside the secondary sheet 700 for electrical connection purposes (as illustrated). The assembled solar panel 800 may be nailed or otherwise fixed to a roof (e.g., using asphalt, adhesives, foams), or integrated into a roof shingle, roof tile or other roof covering product. Additionally, solar panel 800 may be attached to other photovoltaic (solar) products or adjacent non-photovoltaic roofing material. Optionally, for some embodiments, stiffening and/or strengthening materials or parts may be incorporated into the low profile solar panel to improve its rigidity. For example, aluminum polyethylene aluminum (APA) may be incorporated into the low profile solar panel to improve the panel's rigidity.

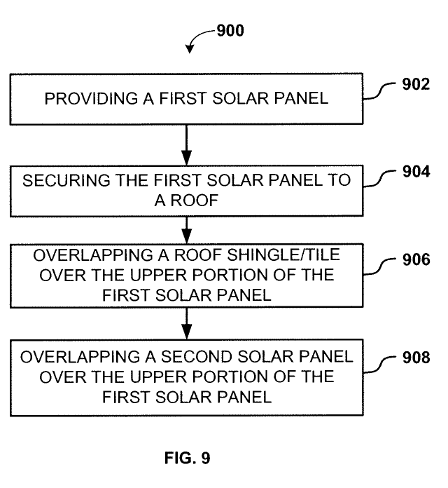

Turning now to FIG. 9, a flowchart is depicted illustrating a method 900 for mounting low profile solar panel onto a roof in accordance with one embodiment of the invention. The method 900 begins at operation 902, where a first solar panel is provided comprising a solar laminate and a flexible material sheet adhered to the solar laminate. In accordance with an embodiment of the invention, the flexible material sheet is configured to operate as a frame that supports the solar laminate, houses the solar laminate, and interfaces with a conventional roof shingle or roof tile in an overlapping fashion.

Next, in operation 904, the first solar panel is secured to the roof using any of number of different means including, but not limited to, nails, foam, asphalt, adhesives, and tack-down strips. Once secured to the roof, a roof shingle or roof tile is placed on the roof in operation 906 such that it overlaps over the upper portion of the first solar panel. In operation 908, a second solar panel is placed over the first solar panel such that it overlaps over the upper portion of the first solar panel.

As used herein, the term module might describe a given unit of functionality that can be performed in accordance with one or more embodiments of the present invention. As used herein, a module might be implemented utilizing any form of hardware, software, or a combination thereof.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in teens of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the teen “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A low profile solar panel, comprising:
a solar laminate; and
a flexible material sheet adhered to the solar laminate, wherein the flexible material sheet is configured to operate as a frame that supports and houses the solar laminate.

2. The low profile solar panel of claim 1, further comprising a secondary sheet, wherein the secondary sheet is disposed on an edge formed by adhering the flexible material sheet to the solar laminate.

3. The low profile solar panel of claim 1, further comprising electrical wiring or circuitry disposed on the solar laminate.

4. The low profile solar panel of claim 3, further comprising a secondary sheet, wherein the secondary sheet is disposed on an edge formed by adhering the flexible material sheet to the solar laminate, such that the secondary sheet covers the electrical wiring or circuitry.

5. The low profile solar panel of claim 1, wherein the low profile solar panel is configured to be attached to a roof.

6. The low profile solar panel of claim 5, wherein the low profile solar panel is configured to be attached to the roof by nails, screws, foam, a tack-down strip or adhesives.

7. The low profile solar panel of claim 6, wherein the tack-down strip is configured to connect the low profile solar panel to overlap a roof shingle or roof tile.

8. The low profile solar panel of claim 1, wherein the low profile solar panel is configured to integrate with roof shingles or roof tiles.

9. The low profile solar panel of claim 1, wherein the low profile solar panel is less than 0.65″ thick.

10. The low profile solar panel of claim 9, wherein the roof shingles are asphalt shingles.

11. The low profile solar panel of claim 1, wherein the flexible material sheet is adhered to the solar laminate using adhesives.

12. The low profile solar panel of claim 1, wherein the solar laminate comprises multiple solar cells.

13. The low profile solar panel of claim 1, further comprising an integrated rain-rail disposed on the solar laminate configured to provide a conduit for rainwater and mate with a rain rail on a second solar panel providing a mechanical interconnection between the low profile solar panel and the second solar panel.

14. The low profile solar panel of claim 2, further comprising an integrated rain-rail disposed on the secondary sheet configured to provide a conduit for rainwater and mate with a rain rail on a second solar panel providing a mechanical interconnection between the low profile solar panel and the second solar panel.

15. A method for mounting solar panels onto a roof, comprising:
providing a first solar panel, comprising:
a solar laminate, and
a flexible material sheet adhered to the solar laminate, wherein the flexible material sheet is configured to operate as a frame that supports the solar laminate, houses the solar laminate, and interfaces with a conventional roof shingle or roof tile in an overlapping fashion;
securing the first solar panel to the roof;
overlapping a roof shingle or roof tile over an upper portion of the first solar panel; and
overlapping a second solar panel over the upper portion of the first solar panel.

16. The method of claim 15, wherein the first solar panel further comprises a secondary sheet, wherein the secondary sheet is disposed on an edge formed by adhering the flexible material sheet to the solar laminate.

17. The method of claim 15, wherein the first solar panel further comprises electrical wiring or circuitry disposed on the solar laminate.

18. The method of claim 17, wherein the first solar panel further comprises a secondary sheet, wherein the secondary sheet is disposed on an edge formed by adhering the flexible material sheet to the solar laminate, such that the secondary sheet covers the electrical wiring or circuitry.

19. The method of claim 15, wherein the first solar panel is secured to the roof using nails, screws, foam, a tack-down strip, or adhesives.

20. The method of claim 19, wherein the tack-down strip overlaps and connects the first solar panel to a roof shingle or roof tile.

21. A building, comprising:
a roof assembly including roof shingles or roof tiles; and
a low profile solar panel, comprising:
a solar laminate, and
a flexible material sheet adhered to the solar laminate, wherein the flexible material sheet is configured to operate as a frame that supports the solar laminate, houses the solar laminate, and interfaces with a conventional roof shingle or roof tile in an overlapping fashion.

22. The building of claim 21, wherein the first solar panel further comprises a secondary sheet, wherein the secondary sheet is disposed on an edge formed by adhering the flexible material sheet to the solar laminate.

23. The building of claim 21, wherein the first solar panel further comprises electrical wiring or circuitry disposed on the solar laminate.

24. The building of claim 23, wherein the first solar panel further comprises a secondary sheet, wherein the secondary sheet is disposed on an edge formed by adhering the flexible material sheet to the solar laminate, such that the secondary sheet covers the electrical wiring or circuitry.

25. The building of claim 21, wherein the first solar panel is secured to the roof using nails, screws, foam, a tack-down strip, or adhesives.

26. The building of claim 25, wherein the tack-down strip overlaps and connects the first solar panel to a roof shingle or roof tile.
